(19) United States
(12) Patent Application Publication
(10) Pub. No.: US 2012/0049896 A1
(43) Pub. Date: Mar. 1, 2012

(54) SOURCE DRIVER HAVING AMPLIFIERS INTEGRATED THEREIN

(76) Inventors: Yung-Hsu Lin, Hsin-Chu (TW); Chun-Fan Chung, Hsin-Chu (TW); Yu-Hsi Ho, Hsin-Chu (TW)

(21) Appl. No.: 12/940,032

(22) Filed: Nov. 4, 2010

(30) Foreign Application Priority Data
Aug. 31, 2010 (TW) 099129325

(51) Int. Cl. H03K 3/00

(52) U.S. Cl. 327/108

(57) ABSTRACT

A source driver includes at least one source driving unit and a voltage source generation circuit. The voltage source generation circuit is used for generating a first voltage provided for the at least one source driving unit. The voltage source generation circuit includes a first amplifier integrated in a source driving unit of the at least one source driving unit. The first voltage is provided to the at least one source driving unit.

### BACKGROUND OF THE INVENTION

1. Field of the Invention

The present invention is related to a source driver, and particularly to a source driver having amplifiers integrated therein.

2. Description of the Prior Art

Frame rate, size, resolution, and output loading of a liquid crystal panel increases quickly with development of the liquid crystal panel, so that operation temperature and power consumption of source drivers of the liquid crystal panel become significant problems.

Please refer to FIG. 1A and FIG. 1B. FIG. 1A is a diagram illustrating a source driver 100 according to the prior art, and FIG. 1B is a diagram illustrating a source driver 110 having an additional half voltage source according to the prior art. As shown in FIG. 1A, a voltage drop between an amplifier 102 and an amplifier 104 is a high voltage AVDD minus a low voltage AGND, where the amplifier 102 for driving odd data lines is called a positive output stage amplifier, and the amplifier 104 for driving even data lines is called a negative output stage amplifier. As shown in FIG. 1B, the source driver 110 has the additional half voltage source which can generate a half voltage VH. Therefore, a voltage drop of an amplifier 1102 of the source driver 110 is the high voltage AVDD minus the half voltage VH, and a voltage drop of an amplifier 1104 is the half voltage VH minus the low voltage AGND. By decreasing the voltage drop of the amplifier 1102 and the voltage drop of the amplifier 1104, operation temperature and power consumption of the source driver 110 are decreased significantly. But, the source driver 110 requires the additional half voltage source, so the additional half voltage source increases cost of the source driver 110.

### SUMMARY OF THE INVENTION

An embodiment of the present invention provides a source driver having amplifiers integrated therein. The source driver includes at least one source driving unit and a voltage source generation circuit. Each source driving unit of the at least one source driving unit is used for driving at least one corresponding data line of a liquid crystal panel; and the voltage source generation circuit is used for generating a first voltage for the at least one source driving unit, wherein a first amplifier of the voltage source generation circuit is integrated in a source driving unit of the at least one source driving unit.

The present invention provides a source driver having amplifiers integrated therein. The source driver utilizes a voltage source generation circuit to generate a half voltage for a plurality of amplifiers of each source driving unit driving odd data lines and a plurality of amplifiers of the each source driving unit driving even data lines. Thus, the present invention can reduce power consumption of the source driver. In addition, the present invention can also simplify complexity and devices of a power circuit on a printed circuit board to reduce the source driver cost.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1A is a diagram illustrating a source driver according to the prior art.

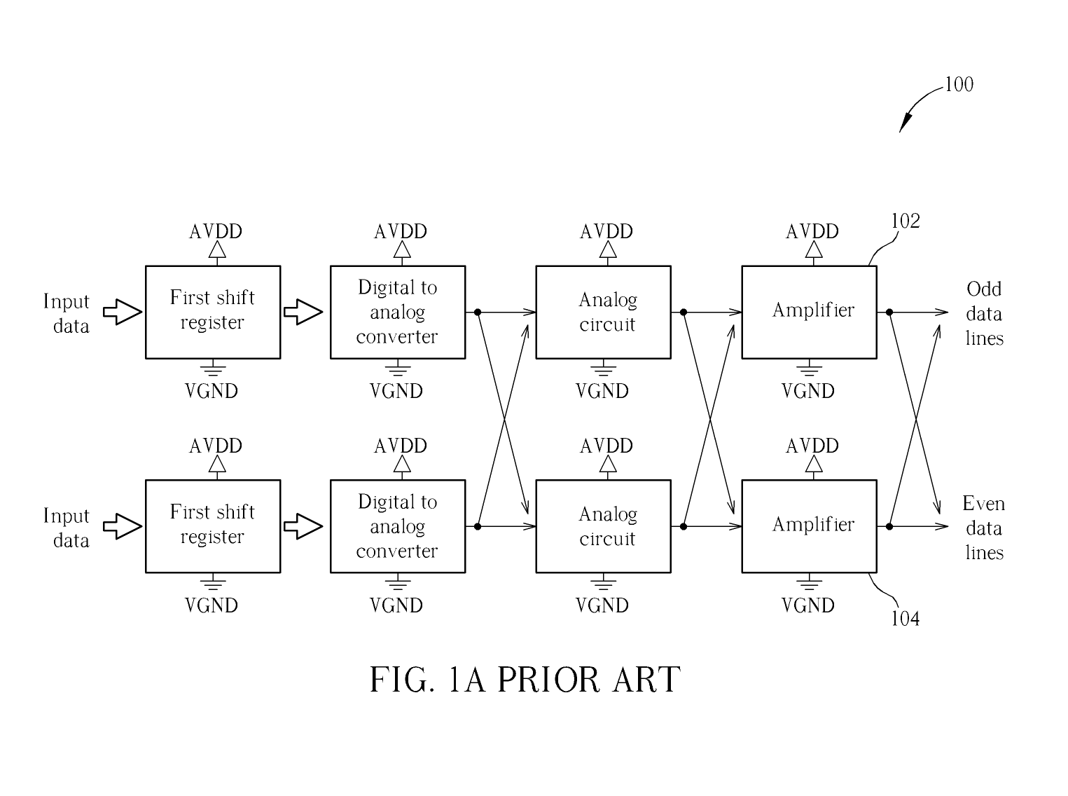

FIG. 1B is a diagram illustrating a source driver having an additional half voltage source according to the prior art.

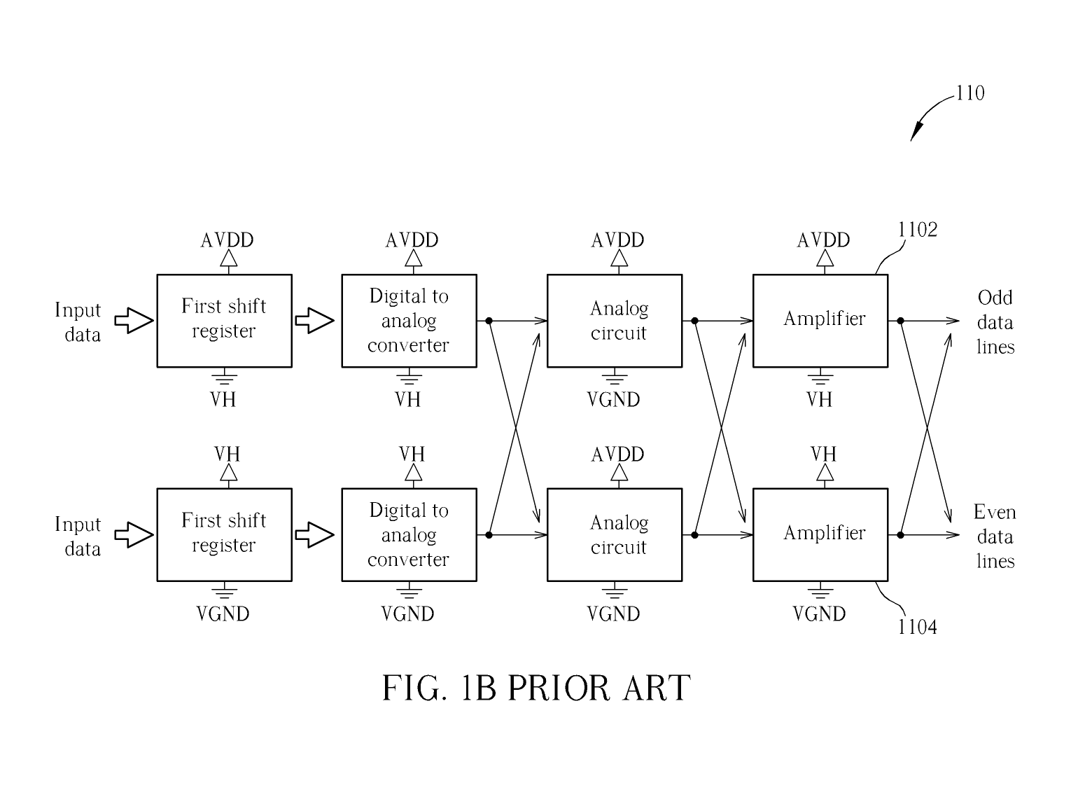

FIG. 2 is a diagram illustrating a source driver having amplifiers integrated therein according to an embodiment of the present invention.

FIG. 3 is a diagram illustrating a source driver having amplifiers integrated therein according to another embodiment of the present invention.

FIG. 4 is a diagram illustrating a source driver having amplifiers integrated therein according to another embodiment of the present invention.

FIG. 5 is a diagram illustrating a source driver having amplifiers integrated therein according to another embodiment of the present invention.

FIG. 6 is a diagram illustrating a source driver having amplifiers integrated therein according to another embodiment of the present invention.

FIG. 7 is a diagram illustrating a source driver having amplifiers integrated therein according to another embodiment of the present invention.

### DETAILED DESCRIPTION

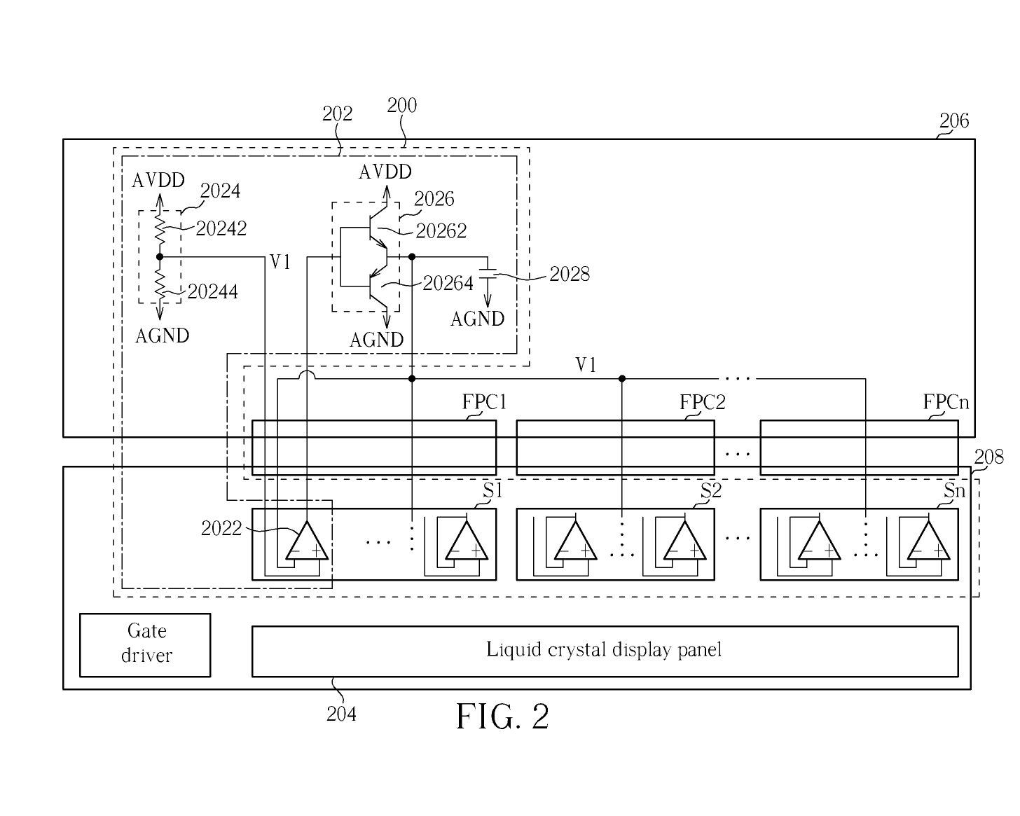

Please refer to FIG. 2. FIG. 2 is a diagram illustrating a source driver 200 having amplifiers integrated therein according to an embodiment of the present invention. The source driver 200 includes a plurality of source driving units S1-Sn and a voltage source generation circuit 202. Each source driving unit of the plurality of source driving units S1-Sn has a plurality of amplifiers used for driving at least one corresponding data line of the liquid crystal panel 204. The voltage source generation circuit 202 is used for generating a first voltage V1 for amplifiers within the plurality of source driving units S1-Sn. The voltage source generation circuit 202 includes a first amplifier 2022, a first voltage divider 2024, a first push-pull amplifier 2026, and a first capacitance 2028, where the first amplifier 2022 is integrated in the source driving unit S1. Because the source driving units S2-Sn also have a plurality of amplifiers, the present invention is not limited to integrating the first amplifier 2022 into the source driving unit S1, and the first amplifier 2022 can be also integrated into another source driving unit.

The first voltage divider 2024 has a first terminal coupled to a high voltage AVDD, a second terminal coupled to a low voltage AGND, and a third terminal coupled to a first input terminal of the first amplifier 2022 for outputting the first voltage V1. The first voltage divider 2024 includes a first resistor 20242 and a second resistor 20244. The first resistor 20242 has a first terminal coupled to the first terminal of the first voltage divider 2024, and a second terminal coupled to the third terminal of the first voltage divider 2024. The second resistor 20244 has a first terminal coupled to the second terminal of the first resistor 20242, and a second terminal coupled to the second terminal of the first voltage divider 2024. As shown in FIG. 2, the first resistor 20242 is equal to the second resistor 20244, so the first voltage V1 is half a sum of the high voltage AVDD and the low voltage AGND. But, the present invention is not limited to the first resistor 20242 being equal to the second resistor 20244. The first resistor 20242 and the second resistor 20244 may be unequal. The first voltage V1 is provided to a plurality of amplifiers of each source driving unit, where each amplifier is used for driving a corresponding data line.

The first push-pull amplifier 2026 is integrated on a printed circuit board 206 outside the plurality of source driving units S1-Sn, where the printed circuit board 206 utilizes a plurality of flexible printed circuit boards (FPCBs) FPC1-FPCn to electrically connect to a substrate 208 on which the plurality of source driving units S1-Sn are located. The first push-pull amplifier 2026 has a first terminal coupled to an output terminal of the first amplifier 2022, a second terminal coupled to the high voltage AVDD, a third terminal coupled to the low voltage AGND, and a fourth terminal coupled to a second input terminal of the first amplifier 2022 for outputting the first voltage V1. The first push-pull amplifier 2026 includes a first bipolar 20262 and a second bipolar 20264, where the first bipolar 20262 is an NPN type bipolar transistor, and the second bipolar 20264 is a PNP type bipolar transistor. The first bipolar 20262 has a first terminal coupled to the second terminal of the first push-pull amplifier 2026, a second terminal coupled to the first terminal of the first push-pull amplifier 2026, and a third terminal coupled to the fourth terminal of the first push-pull amplifier 2026. The second bipolar 20264 has a first terminal coupled to the fourth terminal of the first push-pull amplifier 2026, a second terminal coupled to the first terminal of the first push-pull amplifier 2026, and a third terminal coupled to the third terminal of the first push-pull amplifier 2026. The first capacitance 2028 is coupled to the fourth terminal of the first push-pull amplifier 2026 for stabilizing the first voltage V1.

As shown in FIG. 2, the first voltage divider 2024 utilizes the first resistor 20242 and the second resistor 20244 to generate the first voltage V1, and outputs the first voltage V1 to the first input terminal of the first amplifier 2022. The fourth terminal of the first push-pull amplifier 2026 is coupled to the second input terminal of the first amplifier 2022, so the fourth terminal of the first push-pull amplifier 2026 also outputs the first voltage V1. In addition, the first voltage V1 is provided to the plurality of amplifiers of the plurality of source driving units S1-Sn by the plurality of flexible printed circuit boards FPC1-FPCn.

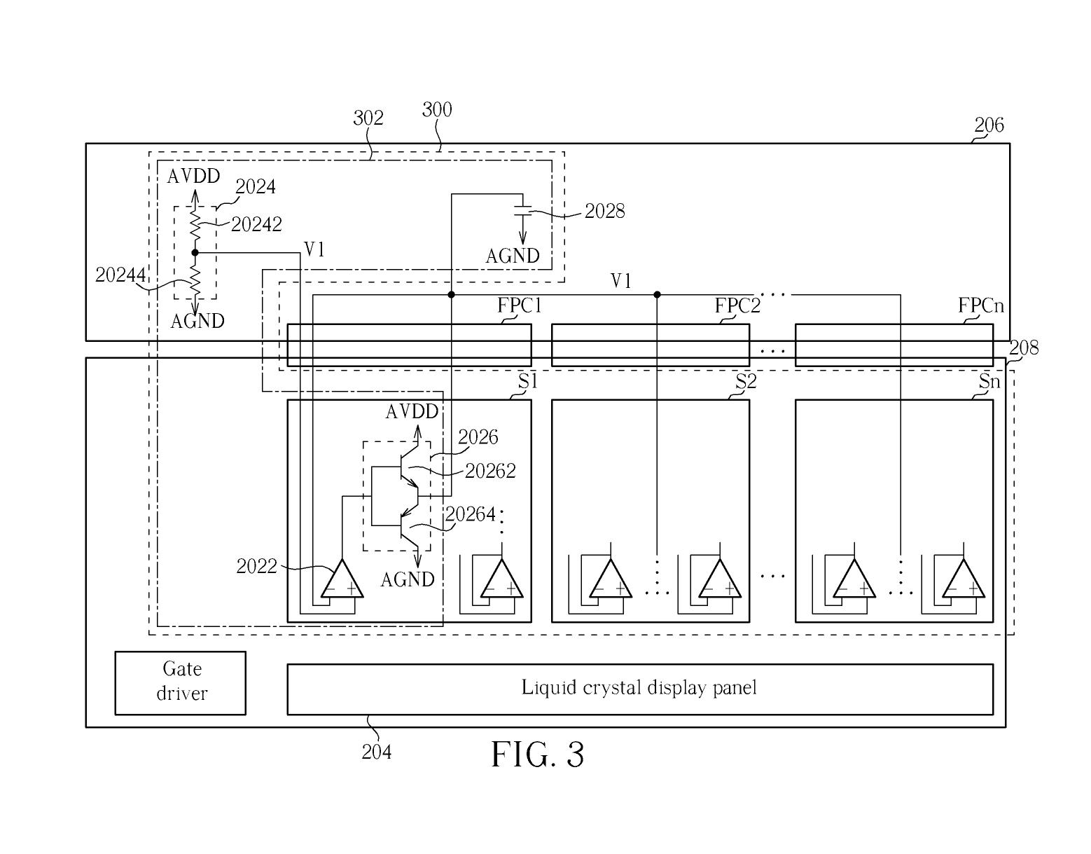

Please refer to FIG. 3. FIG. 3 is a diagram illustrating a source driver 300 having amplifiers integrated therein according to another embodiment of the present invention. A difference between the source driver 300 and the source driver 200 is that the first push-pull amplifier 2026 of a voltage source generation circuit 302 of the source driver 300 is integrated into the source driving unit S1. But, the present invention is not limited to integrating the first push-pull amplifier 2026 into the source driving unit S1, and the first push-pull amplifier 2026 can be also integrated into another source driving unit. Further, subsequent operational principles of the source driver 300 are the same as the source driver 200, so further description thereof is omitted for simplicity.

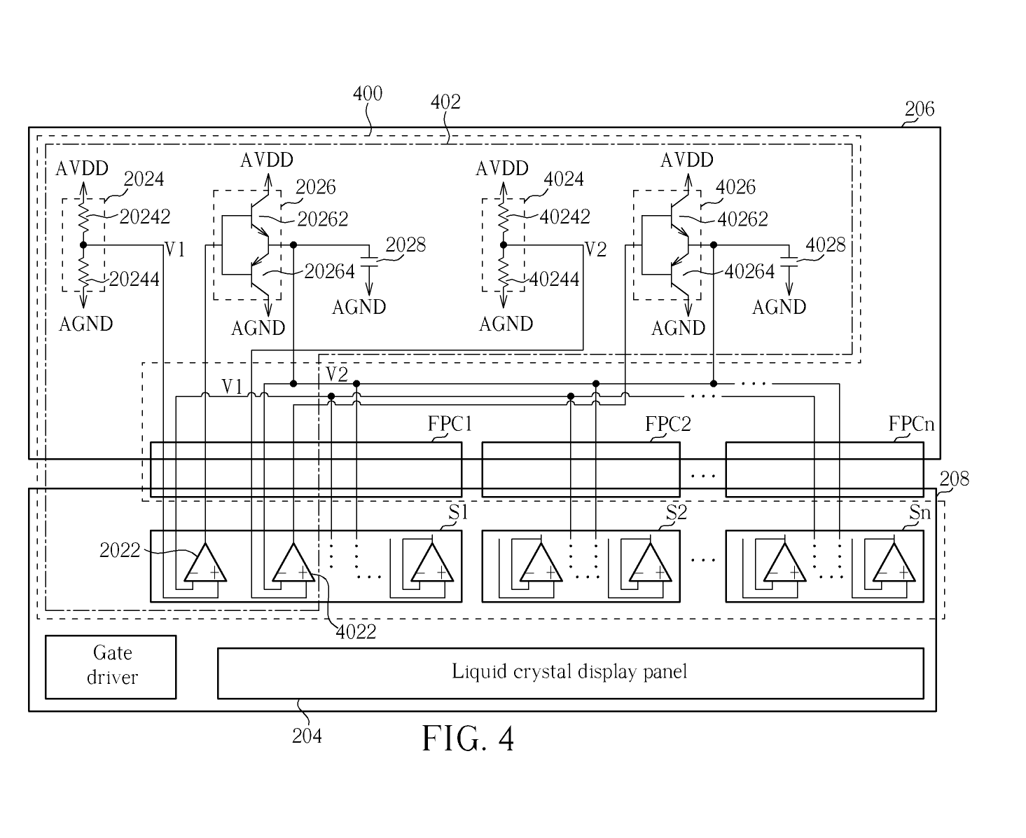

Please refer to FIG. 4. FIG. 4 is a diagram illustrating a source driver 400 having amplifiers integrated therein according to another embodiment of the present invention. A difference between the source driver 400 and the source driver 200 is that a voltage source generation circuit 402 of the source driver 400 further includes a second amplifier 4022, a second voltage divider 4024, a second push-pull amplifier 4026, and a second capacitance 4028, where the second amplifier 4022 is integrated into the source driving unit S1. But, the present invention is not limited to integrating the second amplifier 4022 into the source driving unit S1, and the second amplifier 4022 can also be integrated into another source driving unit.

The second voltage divider 4024 has a first terminal coupled to the high voltage AVDD, a second terminal coupled to the low voltage AGND, and a third terminal coupled to a first input terminal of the second amplifier 4022 for outputting a second voltage V2. The second voltage divider 4024 includes a third resistor 40242 and a fourth resistor 40244. The third resistor 40242 has a first terminal coupled to the first terminal of the second voltage divider 4024, and a second terminal coupled to the third terminal of the second voltage divider 4024. The fourth resistor 40244 has a first terminal coupled to the second terminal of the third resistor 40242, and a second terminal coupled to the second terminal of the second voltage divider 4024. As shown in FIG. 4, the third resistor 40242 is equal to the fourth resistor 40244, so the second voltage V2 is half the sum of the high voltage AVDD and the low voltage AGND. But the present invention is not limited to the third resistor 40242 being equal to the fourth resistor 40244. The third resistor 40242 and the fourth resistor 40244 may be unequal. The first voltage V1 is provided to a plurality of amplifiers of each source driving unit for driving odd data lines and the second voltage V2 is provided to a plurality of amplifiers of the each source driving unit for driving even data lines, where each amplifier is used for driving a corresponding data line.

The second push-pull amplifier 4026 is integrated on the printed circuit board 206 outside the plurality of source driving units S1-Sn, where the printed circuit board 206 utilizes the plurality of flexible printed circuit boards (FPCBs) FPC1-FPCn to electrically connect to the substrate 208 on which the plurality of source driving units S1-Sn are located. The second push-pull amplifier 4026 has a first terminal coupled to an output terminal of the second amplifier 4022, a second terminal coupled to the high voltage AVDD, a third terminal coupled to the low voltage AGND, and a fourth terminal coupled to a second input terminal of the second amplifier 4022 for outputting the second voltage V2. The second push-pull amplifier 4026 includes a third bipolar 40262 and a fourth bipolar 40264, where the third bipolar 40262 is an NPN type bipolar transistor and the fourth bipolar 40264 is a PNP type bipolar transistor. The third bipolar 40262 has a first terminal coupled to the second terminal of the second push-pull amplifier 4026, a second terminal coupled to the first terminal of the second push-pull amplifier 4026, and a third terminal coupled to the fourth terminal of the second push-pull amplifier 4026. The fourth bipolar 40264 has a first terminal coupled to the fourth terminal of the second push-pull amplifier 4026, a second terminal coupled to the first terminal of the second push-pull amplifier 4026, and a third terminal coupled to the third terminal of the second push-pull amplifier 4026. The second capacitance 4028 is coupled to the fourth terminal of the second push-pull amplifier 4026 for stabilizing the second voltage V2.

As shown in FIG. 4, the second voltage divider 4024 utilizes the third resistor 40242 and the fourth resistor 40244 to generate the second voltage V2, and outputs the second voltage V2 to the first input terminal of the second amplifier 4022. The fourth terminal of the second push-pull amplifier 4026 is coupled to the second input terminal of the second amplifier 4022, so the fourth terminal of the second push-pull amplifier 4026 also outputs the second voltage V2. In addition, the second voltage V2 is provided to the plurality of amplifiers of the plurality of source driving units S1-Sn by the plurality of flexible printed circuit boards FPC1-FPCn. Further, subsequent operational principles of the source driver 400 are the same as the source driver 200, so further description thereof is omitted for simplicity.

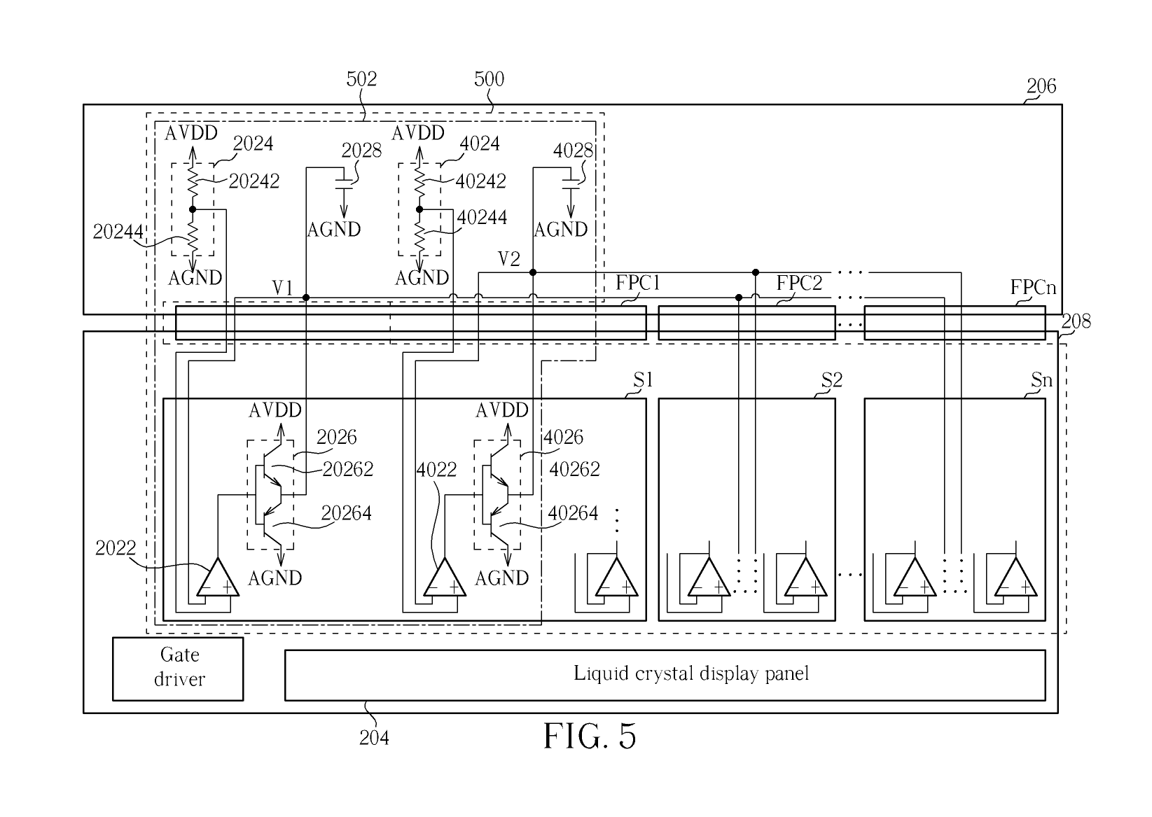

Please refer to FIG. 5. FIG. 5 is a diagram illustrating a source driver 500 having amplifiers integrated therein according to another embodiment of the present invention. A difference between the source driver 500 and the source driver 400 is that the first push-pull amplifier 2026 and the second push-pull amplifier 4026 of a voltage source generation circuit 502 of the source driver 500 are integrated into the source driving unit S1. But, the present invention is not limited to integrating the second push-pull amplifier 4026 into the source driving unit S1, and the second push-pull amplifier 4026 can be also integrated into another source driving unit. Further, subsequent operational principles of the source driver 500 are the same as the source driver 400, so further description thereof is omitted for simplicity.

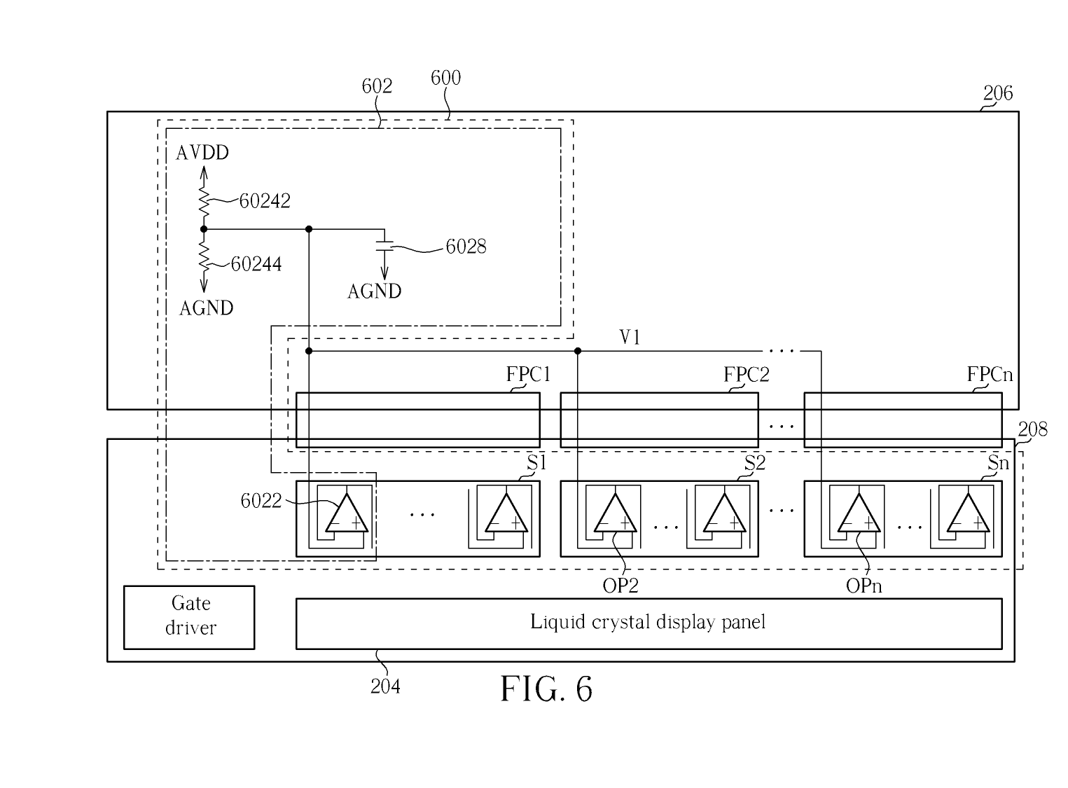

Please refer to FIG. 6. FIG. 6 is a diagram illustrating a source driver 600 having amplifiers integrated therein according to another embodiment of the present invention. The source driver 600 includes a plurality of source driving units S1-Sn and a voltage source generation circuit 602. The voltage source generation circuit 602 includes a third amplifier 6022, a fifth resistor 60242, a sixth resistor 60244, and a third capacitance 6028, where the third amplifier 6022 is integrated into the source driving unit S1 of the plurality of source driving units S1-Sn. But, the present invention is not limited to integrating the third amplifier 6022 into the source driving unit S1. The third amplifier 6022 can also be integrated into another source driving unit. As shown in FIG. 6, the fifth resistor 60242 is equal to the sixth resistor 60244, and the fifth resistor 60242 and the sixth resistor 60244 are used for generating the first voltage V1 and outputting the first voltage V1 to the first input terminal of the third amplifier 6022 and first input terminals of amplifiers OP2-OPn of each source driving unit of the source driving units S2-Sn. But, the present invention is not limited to the fifth resistor 60242 being equal to the sixth resistor 60244. The fifth resistor 60242 and the sixth resistor 60244 may be unequal. Output terminals of the amplifiers OP2-OPn are used for outputting the first voltage V1, and the first voltage V1 is provided to another plurality of amplifiers of the source driving units S1-Sn. Further, subsequent operational principles of the source driver 600 are the same as the source driver 200, so further description thereof is omitted for simplicity.

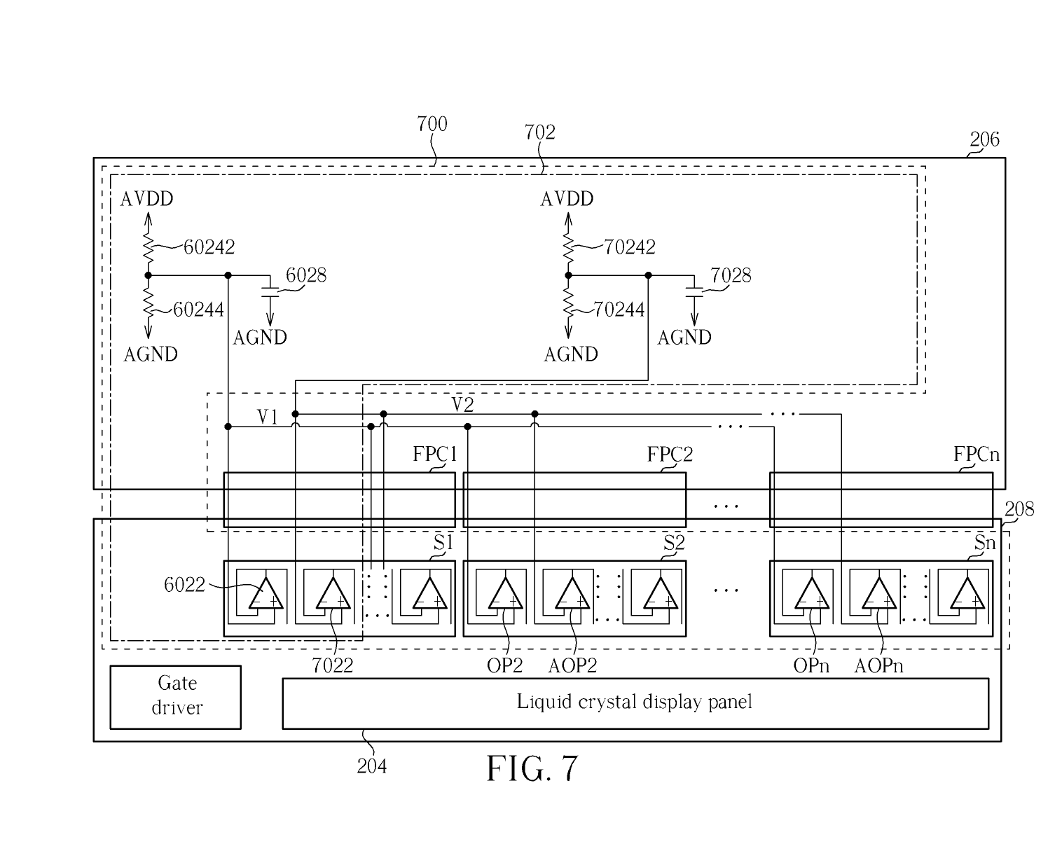

Please refer to FIG. 7. FIG. 7 is a diagram illustrating a source driver 700 having amplifiers integrated therein according to another embodiment of the present invention. A difference between the source driver 700 and the source driver 600 is that a voltage source generation circuit 702 of the source driver 700 further includes a fourth amplifier 7022, a seventh resistor 70242, an eighth resistor 70244, and a fourth capacitance 7028, where the fourth amplifier 7022 is integrated into the source driving unit S1. But, the present invention is not limited to integrating the fourth amplifier 7022 into the source driving unit S1. The fourth amplifier 7022 can be also integrated into another source driving unit.

As shown in FIG. 7, the seventh resistor 70242 is equal to the eighth resistor 70244, and the seventh resistor 70242 and the eighth resistor 70244 are used for generating the second voltage V2 and outputting the second voltage V2 to the first input terminal of the fourth amplifier 7022 and first input terminals of amplifiers AOP2-AOPn of each source driving unit of the source driving units S2-Sn. But, the present invention is not limited to the seventh resistor 70242 being equal to the eighth resistor 70244. The seventh resistor 70242 and the eighth resistor 70244 may be unequal. Output terminals of the amplifiers AOP2-AOPn are used for outputting the second voltage V2, the first voltage V1 is provided to a plurality of amplifiers of each source driving unit for driving odd data lines, and the second voltage V2 is provided to a plurality of amplifiers of each source driving unit for driving even data lines, where each amplifier is used for driving a corresponding data line. Further, subsequent operational principles of the source driver 700 are the same as the source driver 600, so further description thereof is omitted for simplicity.

To sum up, the source driver having amplifiers integrated therein utilizes the voltage source generation circuit to generate the half voltage for the plurality of amplifiers of each source driving unit driving the odd data lines and the plurality of amplifiers of each source driving unit driving the even data lines. Thus, the present invention can reduce power consumption of the source driver. In addition, the source driver having amplifiers integrated therein can also simplify complexity and devices of a power circuit on the printed circuit board to reduce cost of the source driver.

Those skilled in the art will readily observe that numerous modifications and alterations of the device and method may be made while retaining the teachings of the invention.

What is claimed is:

1. A source driver having amplifiers integrated therein, the source driver comprising:
at least one source driving unit, each source driving unit used for driving at least one corresponding data line of a liquid crystal panel; and
a voltage source generation circuit for generating a first voltage for the at least one source driving unit, wherein a first amplifier of the voltage source generation circuit is integrated in a source driving unit of the at least one source driving unit.

2. The source driver of claim 1, wherein the voltage source generation circuit further comprises:
a first voltage divider having a first terminal coupled to a high voltage, a second terminal coupled to a low voltage, and a third terminal coupled to a first input terminal of the first amplifier for outputting the first voltage;
a first push-pull amplifier having a first terminal coupled to an output terminal of the first amplifier, a second terminal coupled to the high voltage, a third terminal coupled to the low voltage, and a fourth terminal coupled to a second input terminal of the first amplifier for outputting the first voltage; and
a first capacitance coupled to the fourth terminal of the first push-pull amplifier for stabilizing the first voltage, wherein the first voltage is provided to the at least one source driving unit.

3. The source driver of claim 2, wherein the first voltage divider comprises:
a first resistor having a first terminal coupled to the first terminal of the first voltage divider, and a second terminal coupled to the third terminal of the first voltage divider; and
a second resistor having a first terminal coupled to the second terminal of the first resistor, and a second terminal coupled to the second terminal of the first voltage divider.

4. The source driver of claim 2, wherein the first push-pull amplifier comprises:
a first bipolar having a first terminal coupled to the second terminal of the first push-pull amplifier, a second terminal coupled to the first terminal of the first push-pull amplifier, and a third terminal coupled to the fourth terminal of the first push-pull amplifier; and
a second bipolar having a first terminal coupled to the fourth terminal of the first push-pull amplifier, a second terminal coupled to the first terminal of the first push-pull amplifier, and a third terminal coupled to the third terminal of the first push-pull amplifier;
wherein the first bipolar is an NPN type bipolar transistor and the second bipolar is a PNP type bipolar transistor.

5. The source driver of claim 2, wherein the first push-pull amplifier is integrated in the source driving unit.

6. The source driver of claim 2, wherein the first push-pull amplifier is integrated on a printed circuit board outside the at least one source driving unit, wherein the printed circuit board utilizes a plurality of flexible printed circuit boards (FPCBs) to electrically connect to a substrate which the at least one source driving unit is located on.

7. The source driver of claim 2, wherein the voltage source generation circuit further comprises a second amplifier, and the second amplifier is also integrated in the source driving unit.

8. The source driver of claim 7, wherein the voltage source generation circuit further comprises:
a second voltage divider having a first terminal coupled to the high voltage, a second terminal coupled to the low voltage, and a third terminal coupled to a first input terminal of the second amplifier for outputting a second voltage;
a second push-pull amplifier having a first terminal coupled to an output terminal of the second amplifier, a second terminal coupled to the high voltage, a third terminal coupled to the low voltage, and a fourth terminal coupled to a second input terminal of the second amplifier for outputting the second voltage; and
a second capacitance coupled to the fourth terminal of the second push-pull amplifier for stabilizing the second voltage;
wherein the second voltage is provided to the at least one source driving unit.

9. The source driver of claim 8, wherein the second voltage divider comprises:
a third resistor having a first terminal coupled to the first terminal of the second voltage divider, and a second terminal coupled to the third terminal of the second voltage divider; and
a fourth resistor having a first terminal coupled to the second terminal of the third resistor, and a second terminal coupled to the second terminal of the second voltage divider.

10. The source driver of claim 8, wherein the second push-pull amplifier comprises:
a third bipolar having a first terminal coupled to the second terminal of the second push-pull amplifier, a second terminal coupled to the first terminal of the second push-pull amplifier, and a third terminal coupled to the fourth terminal of the second push-pull amplifier; and
a fourth bipolar having a first terminal coupled to the fourth terminal of the second push-pull amplifier, a second terminal coupled to the first terminal of the second push-pull amplifier, and a third terminal coupled to the third terminal of the second push-pull amplifier;
wherein the third bipolar is an NPN type bipolar transistor and the fourth bipolar is a PNP type bipolar transistor.

11. The source driver of claim 8, wherein the second push-pull amplifier is integrated in the source driving unit.

12. The source driver of claim 8, wherein the second push-pull amplifier is integrated on the printed circuit board.

13. The source driver of claim 1, wherein the voltage source generation circuit further comprises:
a fifth resistor having a first terminal coupled to a high voltage, and a second terminal coupled to a first input terminal of the first amplifier for outputting the first voltage; and
a sixth resistor having a first terminal coupled to the second terminal of the first resistor, and a second terminal coupled to a low voltage; and
a third capacitance coupled to the second terminal of the first resistor for stabilizing the first voltage;
wherein the first voltage is provided to the at least one source driving unit.

14. The source driver of claim 13, wherein the voltage source generation circuit further comprises a third amplifier, and the third amplifier is also integrated in the source driving unit.

15. The source driver of claim 14, wherein the voltage source generation circuit further comprises:
a seventh resistor having a first terminal coupled to the high voltage, and a second terminal coupled to a first input terminal of the third amplifier for outputting the second voltage;
an eighth resistor having a first terminal coupled to the second terminal of the seventh resistor, and a second terminal coupled to the low voltage; and
a fourth capacitance coupled to the second terminal of the seventh resistor for stabilizing the second voltage;
wherein the second voltage is provided to at least one source driving unit.
